(19) United States
(12) Patent Application Publication
(10) Pub. No.: US 2011/0291188 A1
(43) Pub. Date: Dec. 1, 2011

(54) STRAINED FINFET

(75) Inventors: Kangguo Cheng, Guilderland, NY (US); Bruce B. Doris, Brewster, NY (US); Xuefeng Hua, Guilderland, NY (US); Ying Zhang, Yorktown Heights, NY (US)

(73) Assignee: INTERNATIONAL BUSINESS MACHINES CORPORATION, Armonk, NY (US)

(21) Appl. No.: 12/787,383

(22) Filed: May 25, 2010

(51) Int. Cl. H01L 29/786; H01L 21/336

(52) U.S. Cl. 257/347; 438/157; 257/E29.286; 257/E21.415

(57) ABSTRACT

A FinFET is described incorporating at least two fins extending from a common Si containing layer and epitaxial material grown from the common layer and from sidewalls of the fins to introduce strain to the common layer and the fins to increase carrier mobility.

### BACKGROUND

The present invention relates to a MOSFET and more specifically, to a FINFET having at least two fins.

FinFET devices are becoming a viable approach for continued CMOS scaling such as beyond 32 nm. Forming a strained FinFET, e.g., by embedded SiGe/Si:C in source/drain regions, however, turns out to be very challenging. Prior art FinFET structures, before source/drain epitaxial growth, have a thin fin with flat sidewalls and may have an insulating cap. The fins are formed on a buried oxide layer. After source/drain epitaxial growth on the fin sidewalls, the fin sidewalls have a facet profile extending out from the fin sidewall, leaving a void underneath the facet.

### SUMMARY

A field effect transistor comprising an insulating substrate having an upper surface, a single crystalline silicon containing structure on the upper surface of the substrate, the structure having first regions of substantially the same thickness and at least two spaced apart fins extending upward from the first regions, the fins having sidewalls and an upper surface, a gate dielectric on a plurality of the first regions and on the sidewalls of the at least two fins, a gate conductor on the gate dielectric on the plurality of the first regions and on the sidewalls of the at least two fins, first and second insulating spacers adjacent first and second sidewalls of the gate conductor, an epitaxial layer of a silicon containing material having a relaxed lattice spacing different from the lattice spacing of the first regions and sidewalls, the epitaxial layer extending from the sidewalls of the fins and portions of the first regions whereby the epitaxial layer imparts strain to the portions of the first regions and sidewalls of at least two fins, and contact conductors for making electrical contact to a fin, on each side of the gate conductor to make a source and drain contact, respectively, and to the gate conductor.

### BRIEF DESCRIPTION OF THE SEVERAL VIEWS OF THE DRAWING

These and other features, objects, and advantages of the present invention will become apparent upon consideration of the following detailed description of the invention when read in conjunction with the drawing in which:

FIG. 1 is a three dimensional view of one embodiment of the invention showing a FinFET.

FIG. 2 is a three dimensional view of a semiconductor structure including fins.

FIG. 3 is a three dimensional view of a semiconductor structure including a gate dielectric, gate conductor and cap layer.

FIG. 4 is a three dimensional view of a semiconductor structure including a sidewall spacer on opposite sides of the gate dielectric, gate conductor and cap layer.

FIG. 5 is a three dimensional view of a semiconductor structure including an epitaxial SiGe layer in the source and drain regions.

FIG. 6 is a three dimensional view of an alternate embodiment of the invention showing a trigate FinFET.

### DETAILED DESCRIPTION

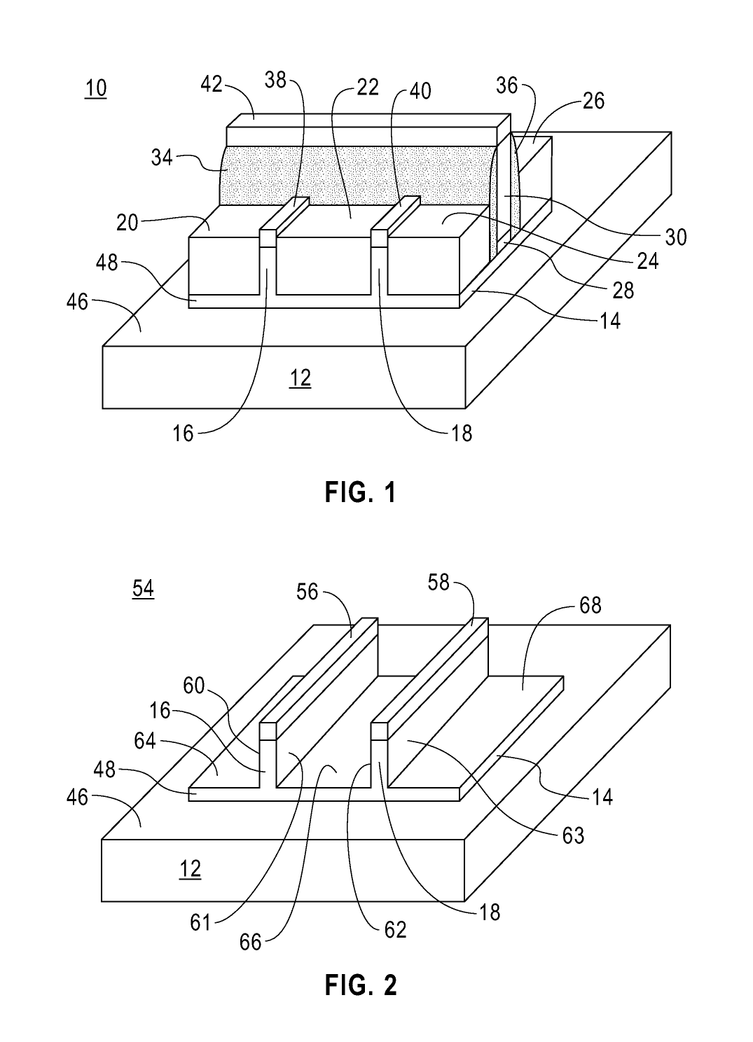

Referring now to the drawing, the process for forming a fin field effect transistor (FinFET) having at least two fins and an epitaxial strain layer on the source and drain is illustrated. FIG. 1 is a three dimensional view of one embodiment of the invention showing a completed FinFET 10. FinFET 10 comprises a substrate 12, a semiconductor structure 14, fins 16 and 18, epitaxial SiGe layers 20, 22, 24 and 26, gate dielectric 28, gate conductor 30, spacers 34 and 36, and metal silicide regions 38, 40 and 42.

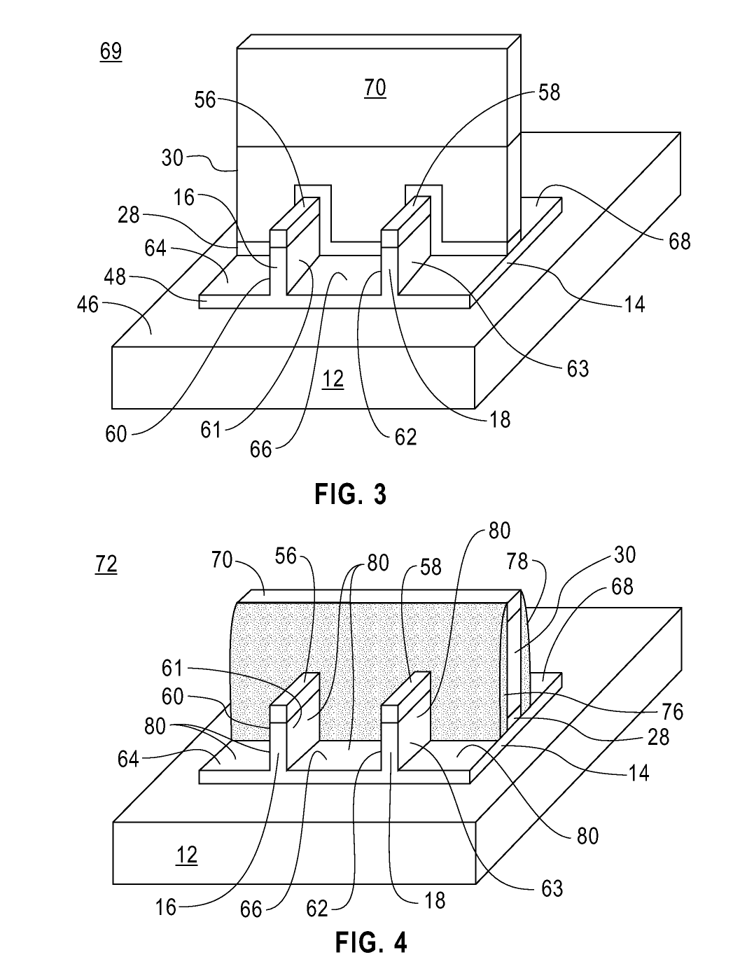

Substrate 12 has an upper surface 46 and may be an insulator such as a buried oxide in a Silicon-on-Insulator (SOI) wafer (shown in part). In an SOI wafer, a silicon substrate (not shown) would be underneath insulating substrate 12 and a silicon layer would be above insulating substrate 12. Above insulating substrate 12 is semiconductor structure 14 which may be formed from a silicon layer (shown in part) above insulating substrate 12. The thickness of the silicon layer should be at least the height of Si fins 16 and 18 above upper surface 46 and may be formed by reactive ion etching (RIE) a pattern for fins into the silicon layer. The RIE is terminated before etching completely through the Si layer to leave fins 16 and 18 extending upward from a lateral Si containing layer 48 shown in FIG. 1. Semiconductor structure 14 is comprised of single crystal Si containing material and comprises lateral Si containing layer 48 and fins 16 and 18 extending upward from the lateral Si containing layer as one solid structure. Gate dielectric 28 may be a high K dielectric constant material. Gate conductor 30 may be patterned polysilicon. Spacers 34 and 36 are formed on sidewalls of gate dielectric 28, gate conductor 30 and cap layer 70 shown in FIGS. 3 and 4 and are of insulating material. Epitaxial SiGe layers 20, 22, 24 and 26 are epitaxial grown on lateral Si containing layer 48 and on the sidewalls of fins 16 and 18. SiGe layers 20, 22, 24 and 26 have strain on both sidewalls and planar surfaces to increase carrier mobility in the channel of FinFET 10. Metal silicide regions 38, 40 and 42 are formed such as by a self aligned process for making electrical contact to each fin 16 and 18 at the source and drain on each fin and to gate conductor 30.

FIG. 2 is a three dimensional view of a semiconductor structure 54 during initial processing to form FinFET 10. Si fins 16 and 18 may be formed by REI with protective oxide caps 56 and 58 forming a mask through which the fins 16 and 18 were protected and formed during etching. Fins 16 and 18 may have a height in the range from 5 nm to 100 nm, preferably from 15 nm to 30 nm and a width in the range from 5 nm to 500 nm and preferably 10-50 nm. As shown in FIG. 2, sidewalls 60, 61, 62 and 63 of fins 16 and 18 respectively are smooth and flat forming a fin of uniform thickness. Sidewalls 60 and 61 of fin 16 and sidewalls 62 and 63 of fin 18 can have any crystalline surface such as {100}, {110}, {111}, {311}, {211}, etc. Preferably, sidewalls 60-63 have (100) surface for nFETs AND (110) FOR pFETs. Lateral Si containing layer 48 has upper surface regions 64, 66 and 68 which are smooth and flat forming a lateral Si layer of uniform thickness. A smooth surface is one that has a Root Mean Square (RMS) roughness of less than 1 nm. Surface regions 64, 66 and 68 can have any crystalline surface. Preferably, surface regions 64, 66 and 68 have {100} or {110} crystalline surface. The perimeter of lateral Si containing layer 48 may be determined by a separate etch step through a mask to etch away lateral Si containing layer 48 to upper surface 46 of substrate 12.

FIG. 3 is a three dimensional view of a semiconductor structure 69 including a gate dielectric 28, gate conductor 30 and cap layer 70 on gate conductor 30. Gate dielectric 28 is first deposited over surface regions 64, 66, and 68, and sidewalls 60, 61, 62 and 63 of fins 16 and 18. Gate dielectric 28 may comprise silicon oxide, silicon nitride, silicon oxynitride, high-k materials, or any combination of these materials. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k materials may further include dopants such as lanthanum or aluminum. Gate conductor 30 is then formed over gate dielectric 28. The channel of FinFET 10 is below gate conductor 30 between the source and drain. Gate conductor 30 is planarized above the highest position of gate dielectric 28 such as where the gate dielectric passes over oxide caps 56 and 58 on fins 16 and 18, respectively. A cap layer 70 is formed on gate conductor 30 which may be, for example, silicon nitride. The cap layer 70, gate conductor 30, and gate dielectric 28 are then patterned. Cap layer 70 may be first patterned and then used as a mask for subsequent etching. The thickness or width of gate conductor 30 corresponds to the width of the gate of FinFET 10 to be formed. Gate conductor 30 may have a width in the range from 5 nm to 100 nm, with 15 nm to 40 nm more typical.

FIG. 4 is a three dimensional view of a semiconductor structure 72 including spacers 76 and 78 formed on opposite sides of gate dielectric 28, gate conductor 30 and cap layer 70. Source/drain halo/extension 80 is formed by ion implantation of ions into sidewalls 60, 61, 62 and 63 of fins 16 and 18 and upper surface regions 64, 66 and 68. Spacers 76 and 78 may be formed by depositing a patterned spacer layer to cover nitride cap layer 70 and sidewalls of gate dielectric 28, gate conductor 30 and cap layer 70. A RIE step removes the spacer layer on horizontal surfaces and shapes spacers 76 and 78 on vertical surfaces to be narrow at the top and thicker at the bottom. Spacers 76 and 78 may comprise, for example, silicon oxide, carbon doped oxide, silicon nitride, perfluorocyclobutane (PFCB), fluorosilicate glass (FSG), any stress memory dielectric materials, and low K materials where K is the dielectric constant and is less than 4. Spacers 76 and 78 each may have a thickness at gate dielectric 28 in the range from 2 nm to 30 nm, with 4 nm to 15 nm more typical.

Optionally, ion implantation of ions into sidewalls 60, 61, 62 and 63 of fins 16 and 18 by using spacers 76 and 78, cap layer 70, oxide cap layers 56 and 58 as a mask forms the correct location of halo/extension implant 80 in upper surface regions 64, 66 and 68 and sidewalls 60, 61, 62 and 63 of fins 16 and 18.

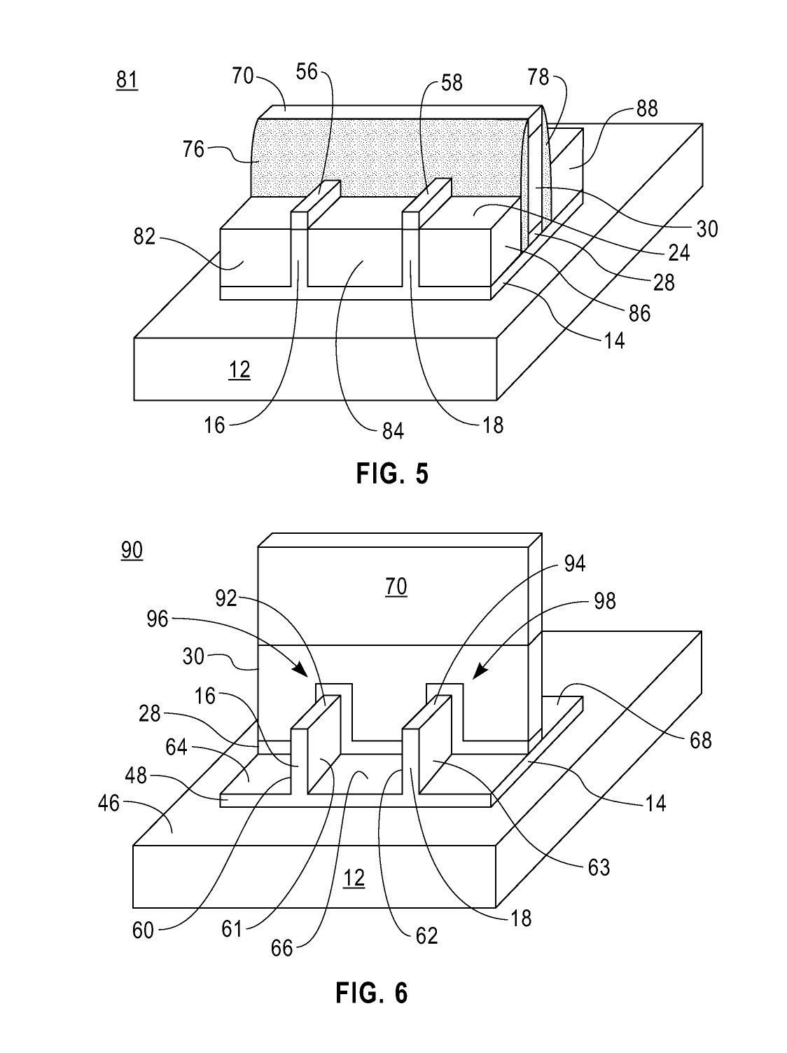

FIG. 5 is a three dimensional view of a semiconductor structure 81 including epitaxial layers 82, 84, 86 and 88 comprising SiGe for a p type FinFET 10 shown in FIG. 1. For an n type FinFET 10, epitaxial layers 82, 84, 86 and 88 may comprise, for example, Si:C. Sidewalls 60, 61, 62 and 63 of fins 16 and 18 and regions 64, 66 and 68 shown in FIG. 4 act as a seed layer for epitaxial growth. Sidewall 60 and region 64 shown in FIG. 4 provide a seed layer for epitaxial layer 82. Sidewalls 61 and 62 and region 66 provide a seed layer for epitaxial layer 84. Sidewall 63 and region 68 provide a seed layer for epitaxial layer 86. Sidewall 63 on the other side of gate conductor 30, not shown, and region 68 provide a seed layer for epitaxial layer 88. Since regions 64, 66, and 68 function as seed layers for epitaxial growth, no voids are formed underneath epitaxial layers 82, 84, 86 and 88. Spacers 76 and 78 do not act as a seed layer if the spacer is an insulator.

Epitaxial layers 82, 84, 86 and 88 can be in-situ doped, doped by ion implantation or doped by plasma doping to dope fins 16 and 18 on either side of gate conductor 30 to form a source and drain. Epitaxial layers 82, 84, 86 and 88 comprise a material having a relaxed lattice spacing different from the lattice spacing of sidewalls 60, 61, 62 and 63 and regions 64, 66 and 68 to provide strain in the channel. For p type FinFETs, the strain on sidewalls 60, 61, 62 and 63 and on regions 64, 66 and 68 should be tensile strain to improve mobility of hole carriers in the channel which is below gate conductor 30 between the source and drain. Tensile strain is obtained from SiGe which has a relaxed lattice spacing greater than Si or SiGe where Ge is less. Ge has a relaxed lattice spacing of about 4% greater than Si and alloys of SiGe have a relaxed lattice spacing linear or proportional to the amount of Si and Ge. For n type FinFETs, the strain on the sidewalls 60, 61, 62 and 62 and regions 64, 66 and 68 should be compressive strain to improve mobility of electron carriers in the channel. Compressive strain is obtained from Si:C which has a lattice spacing less than Si or Si:C where C is less. As shown in FIG. 5, epitaxial layers 82, 84, 86 and 88 may have the same height as fins 16 and 18 and completely fill the space between fins 16 and 18 for optimum mobility performance. Epitaxial layers 82, 84, 86 and 88 may have a height or thickness substantially the same as or greater than the height or thickness of fins 16 and 18.

A relaxed lattice spacing is the lattice spacing of crystalline material with no strain such as when the material is a non epitaxial layer or a layer on a non crystalline substrate. A strained epitaxial layer is a layer with a crystal lattice that is aligned with the crystal lattice of crystalline material having a different crystal lattice spacing. As the difference in crystal lattice spacing increases between two materials, epitaxial layers will tend to relax (become unstrained and non epitaxial) at a thinner thickness. The thickness at which a strained epitaxial layer relaxes due to the difference in the relaxed crystal lattice spacing of the crystalline material is known as the critical thickness.

Next, oxide caps 56 and 58 are removed from fins 16 and 18 up to spacers 76 and 78. Nitride cap 70 is removed from gate conductor 30. A metal may be formed over exposed fins 16 and 18 and gate conductor 30 and heated to react the metal with Si to form a metal silicide such as Ni silicide. Unreacted metal is removed via a selective etch. The metal silicide on fins 16 and 18 provide contact conductors for making electrical contact to each fin. The fins on one side of gate conductor 30 forms contacts to the source of FinFET 10 shown in FIG. 1 and the fins on the other side of gate conductor 30 forms the contacts to the drain of FinFET 10. The metal silicide on gate conductor 30 provides a contact conductor for making electrical contact to the gate of FinFET 10.

FIG. 6 is a three dimensional view of an alternate embodiment of the invention where the FinFET may be a trigate. In FIG. 6, a semiconductor structure 90 including a gate dielectric 28, gate conductor 30 and cap layer 70 on gate conductor 30 is shown. Gate dielectric 28 is formed over surface regions 64, 66, and 68, sidewalls 60, 61, 62 and 63 and upper surfaces 92 and 94 of fins 16 and 18. Gate conductor 30 is formed over gate dielectric 28 to form a trigate FinFET on fins 16 and 18. Trigate FinFET 96 is formed by sidewall 60, upper surface 92 and sidewall 61 below gate dielectric 28 and gate conductor 30. Trigate FinFET 98 is formed by sidewall 62, upper surface 94 and sidewall 63 below gate dielectric 28 and gate conductor 30. Trigate FinFETs 96 and 98 may be completed as described with reference to FIGS. 4 and 5 except upper surfaces 92 and 94 may be implanted with ions to form halo/extension 80 for the FETs on upper surfaces 92 and 94.

Gate conductor 30 is planarized above the highest position of gate dielectric 28 such as where the gate dielectric passes over upper surfaces 92 and 94 of fins 16 and 18, respectively. A cap layer 70 is formed on gate conductor 30 which may be, for example, silicon nitride. The cap layer 70, gate conductor 30, and gate dielectric 28 are then patterned. Cap layer 70 may be first patterned and then used as a mask for subsequent etching. The thickness or width of gate conductor 30 corresponds to the width of the trigate of FinFETs 96 and 98. Gate conductor 30 may have a width in the range from 5 nm to 100 nm, with 15 nm to 40 nm more typical.

In FIGS. 1-6, like references are used for functions corresponding to the apparatus of an earlier Figure.

While there has been described and illustrated a FinFET comprising at least two spaced apart fins and epitaxial layers of a different relaxed lattice spacing grown on the fins and semiconductor regions between the fins to impart strain to increase carrier mobility, it will be apparent to those skilled in the art that modifications and variations are possible without deviating from the broad scope of the invention which shall be limited solely by the scope of the claims appended hereto.

What is claimed is:

1. A field effect transistor comprising:
an insulating substrate having an upper surface,
a single crystalline silicon containing structure on said upper surface of said substrate,
said structure having first regions of substantially the same thickness and at least two spaced apart fins extending upward from said first regions,
said fins having sidewalls and an upper surface,
a gate dielectric on a plurality of said first regions and on said sidewalls of said at least two fins,
a gate conductor on said gate dielectric on said plurality of said first regions and on said sidewalls of said at least two fins,
first and second insulating spacers adjacent first and second sidewalls of said gate conductor,
an epitaxial layer of a silicon containing material having a relaxed lattice spacing different from the lattice spacing of said first regions and sidewalls, said epitaxial layer extending from said sidewalls of said fins and portions of said first regions whereby said epitaxial layer imparts strain to said portions of said first regions and sidewalls of at least two fins, and
contact conductors for making electrical contact to a fin on each side of said gate conductor to make a source and drain contact, respectively, and to said gate conductor.

2. The field effect transistor of claim 1 wherein said gate conductor has a width in the range from 5 nm to 100 nm.

3. The field effect transistor of claim 1 wherein said gate dielectric and gate conductor have a height higher than said at least two fins.

4. The field effect transistor of claim 1 wherein said epitaxial layer is selected from the group consisting of SiGe and Si:C.

5. The field effect transistor of claim 1 wherein one of said first regions extends between two of said at least two fins and wherein a portion of said epitaxial layer extends between said two fins and extends from said one of said first regions.

6. The field effect transistor of claim 1 wherein said one of said first regions is adjacent said first insulating spacer.

7. The field effect transistor of claim 1 wherein said epitaxial layer extends from each sidewall of said at least two fins on both sides of said gate conductor.

8. The field effect transistor of claim 1 wherein said at least two fins and said first regions are Si.

9. The field effect transistor of claim 1 wherein said contact conductors include metal silicide.

10. The field effect transistor of claim 1 wherein said gate conductor includes polysilicon.

11. The field effect transistor of claim 1 wherein said gate dielectric is on said upper surface of at least two of said fins and wherein said gate conductor is on said gate dielectric on said upper surface of at least two of said fins to form two trigate FinFETs.

12. A method for forming a field effect transistor comprising:
selecting a layer of single crystal silicon containing semiconductor material on an insulating substrate,
forming in said layer first regions of substantially the same thickness and at least two spaced apart fins extending upward from said first regions,
said fins having sidewalls and an upper surface,
forming a gate dielectric on a plurality of said first regions and on said sidewalls,
forming a gate conductor on said gate dielectric on said plurality of said first regions and on said sidewalls of said at least two fins,
forming first and second insulating spacers adjacent first and second sidewalls of said gate conductor,
forming an epitaxial layer of a silicon containing material having a relaxed lattice spacing different from the lattice spacing of said first regions and sidewalls, said epitaxial layer extending from said sidewalls of said fins and portions of said first regions whereby said epitaxial layer imparts strain to said portions of said first regions and sidewalls of at least two fins, and
forming contact conductors for making electrical contact to a fin on each side of said gate conductor to make a source and drain contact, respectively, and to said gate conductor to make a gate contact.

13. The method of claim 12 wherein gate conductor has a width in the range from 5 nm to 100 nm.

14. The method of claim 12 wherein said gate dielectric and gate conductor are formed to a height higher than said at least two fins.

15. The method of claim 12 wherein said epitaxial layer is selected from the group consisting of SiGe and Si:C.

16. The method of claim 12 wherein one of said first regions are formed to extend between two of said at least two fins and wherein a portion of said epitaxial layer is formed to extend between said two fins and extends from said one of said first regions.

17. The method of claim 12 wherein said one of said first regions is formed adjacent said first insulating spacer.

18. The method of claim 12 wherein said epitaxial layer extends from each sidewall of said at least two fins on both sides of said gate conductor.

19. The method of claim 12 wherein said at least two fins and said first regions are Si.

20. The method of claim 12 wherein said forming contact conductors include forming metal silicide.

21. The method of claim 12 wherein said gate conductor includes polysilicon.

22. The method of claim 12 further including forming a gate dielectric on said upper surface of at least two of said fins and forming a gate conductor on said gate dielectric on said upper surface of at least two of said fins to form two trigate FinFETs.
